(19) United States
(12) Patent Application Publication
(10) Pub. No.: US 2004/0163585 A1
(43) Pub. Date: Aug. 26, 2004

(54) Method for manufacturing polycrystalline silicon thin film and thin film transistor fabricated using polycrystalline silicon thin film manufactured by the manufacturing

(75) Inventors: Ji Yong Park, Suwon-city (KR); Hye Hyang Park, Suwon-city (KR)

Correspondence Address: STAAS & HALSEY LLP, SUITE 700, 1201 NEW YORK AVENUE, N.W., WASHINGTON, DC, 20005, US

(73) Assignee: Samsung SDI Co., Ltd., Suwon-city (KR)

(21) Appl. No.: 10/690,507

(22) Filed: Oct. 23, 2003

(30) Foreign Application Priority Data
Feb. 26, 2003 (KR) 2003-12101

(51) Int. Cl. C30B 23/00; C30B 25/00; C30B 28/12; C30B 28/14

(52) U.S. Cl. 117/84

(57) ABSTRACT

A method of manufacturing polycrystalline silicon thin film using a laser beam to crystallize amorphous silicon thin film, the method including overlappingly irradiating the laser beam onto a region wider than 0.5 μm when crystallizing the amorphous silicon thin film.

### CROSS-REFERENCE TO RELATED APPLICATIONS

This application claims the benefit of Korean Patent Application No. 2003-12101, filed on Feb. 26, 2003, under 35 U.S.C. § 119, the entirety of which is hereby incorporated by reference.

### BACKGROUND OF THE INVENTION

1. Field of the Invention

The present invention relates to a method for manufacturing polycrystalline silicon thin film and a thin film transistor, and, more particularly, to a method for manufacturing polycrystalline silicon thin film capable of lengthening the width of grains of polycrystalline silicon having a cylindrical shape, and a thin film transistor using the polycrystalline silicon thin film manufactured by the manufacturing method.

2. Description of the Related Art

It is reported that polycrystalline or single crystalline grains are capable of forming large silicon grains using sequential lateral solidification (SLS) crystallization technology, and a thin film transistor (TFT) fabricated using the large silicon grains has characteristics similar to the characteristics of a TFT fabricated using single crystal silicon.

In order to realize that, it is disclosed in PCT international patent No. WO97/45827 and U.S. Pat. No. 6,322,625 that amorphous silicon on the whole substrate is converted into polycrystalline silicon, or only a selected region on the substrate is crystallized by the SLS technology after depositing the amorphous silicon.

Furthermore, when fabricating TFTs for a liquid crystal display (LCD) device comprising a driver and pixel array by forming large silicon grains using the SLS crystallization technology, as disclosed in U.S. Pat. No. 6,177,391, characteristics of TFTs similar to the characteristics of TFTs fabricated using single crystalline silicon can be obtained, since a barrier effect of a grain boundary to a charge carrier direction is minimized in the case that the direction of an active channel is parallel to the growing direction of grains grown by the SLS crystallization method. TFT characteristics are greatly deteriorated in the case that the direction of the active channel is perpendicular to the growing direction of the grains, because a plurality of grain boundaries act as a trap of the charge carriers.

This method for crystallizing the crystalline silicon is performed by irradiating a laser beam onto an amorphous silicon layer two or more times using the SLS method, so that the laser beam is overlapped on the layer, thereby growing the side of crystalline silicon. Polycrystalline silicon grains manufactured using this method are characterized in that they are formed in a cylinder shape, which is long in a direction, because grain boundaries are formed between adjacent grains due to the limited size of the grains.

Actually, there are cases in which TFTs inside a driving circuit and TFTs in a pixel cell region generally have an angle of 90° to one another when fabricating an active matrix display, wherein the uniformity of the device can be improved by fabricating the active matrix display in such a way that the direction of the active channel regions is inclined to the crystal growing direction at an angle of 30° to 60° in order to improve the uniformity of characteristics between TFTs, while the characteristics of each TFT are not greatly deteriorated.

However, it is likely that fatal grain boundaries are included in the active channel regions, since this method also uses grains having a limited size formed by the SLS crystallization technology. Therefore, there is a problem in that unpredictable non-uniformity causes differences of characteristics between TFTs in this method.

Furthermore, TFT characteristics vary according to a gap (width of grains) between grains having the same length and growing direction which are arranged side to side, even in the case that the direction of the active channels is parallel to the grain growing direction. There is a problem in that the mobility of an electric field is greatly deteriorated by a scattering effect during charge transfer in the case that the width of the grains is small.

Therefore, a manufacturing method for manufacturing grains having grain width of a certain size or more is required.

### SUMMARY OF THE INVENTION

Therefore, in order to solve the foregoing and/or other problems of the related art, it is an aspect of the present invention to provide a polycrystalline silicon thin film manufacturing method capable of manufacturing polycrystalline silicon thin film having superior characteristics.

Furthermore, it is another aspect of the present invention to provide a thin film transistor having superior current characteristics by using the manufacturing method.

Additional aspects and/or advantages of the invention will be set forth in part in the description which follows and, in part, will be obvious from the description, or may be learned by practice of the invention.

In order to achieve the foregoing and/or other aspects, the present invention provides a method of manufacturing polycrystalline silicon thin film using a laser beam to crystallize amorphous silicon thin film, the method comprising overlappingly irradiating the laser beam onto a region wider than 0.5 μm when crystallizing the amorphous silicon thin film.

Furthermore, the present invention provides a method of manufacturing polycrystalline silicon thin film by crystallizing amorphous silicon using a laser beam, the method comprising using a mask with a laser transmission region that is wider than a laser non-transmission region by more than 1 μm.

### BRIEF DESCRIPTION OF THE DRAWINGS

These and other aspects and advantages of the invention will become apparent and more readily appreciated from the following description of the preferred embodiments, taken in conjunction with the accompanying drawings of which:

FIG. 1A and FIG. 1B are drawings showing a conventional SLS crystallization method according to an embodiment of the present invention, and a rough shape of polycrystalline silicon manufactured by the method;

FIG. 2A to FIG. 2D are photographs showing the structure of polycrystalline silicon grains formed by varying the width of the overlapped region to 0.5, 1, 1.5 and 2 μm, respectively, according to embodiments of the present invention;

FIG. 3 is a graph showing a value for quantifying the width of the grains at positions which are respectively 1, 1.75 and 2.5 μm distanced from primary grain boundaries in a polycrystalline silicon thin film having a length of 3.5 μm and the grain structure of FIG. 2A to FIG. 2D;

FIG. 4 is a graph showing an electric field mobility of a TFT fabricated using a polycrystalline silicon thin film having the structure of FIG. 2A to FIG. 2D; and

FIG. 5 is a graph showing threshold voltage characteristics of a TFT fabricated using the polycrystalline silicon thin film having the structure of FIG. 2A to FIG. 2D.

### DETAILED DESCRIPTION OF THE PREFERRED EMBODIMENTS

Reference will now be made in detail to the present preferred embodiments of the present invention, examples of which are illustrated in the accompanying drawings, wherein like reference numerals refer to the like elements throughout. The embodiments are described below in order to explain the present invention by referring to the figures.

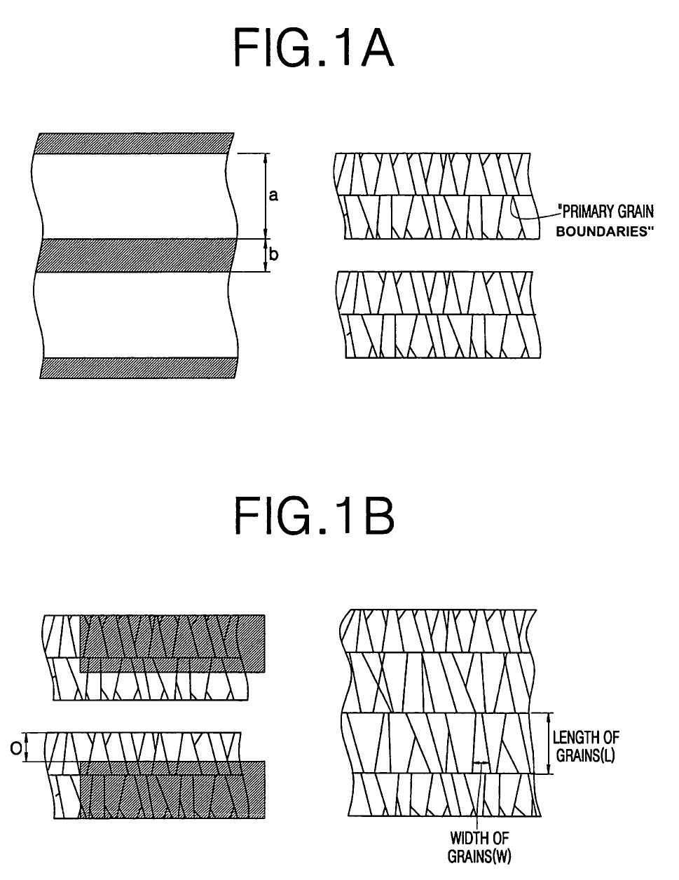

In FIG. 1A, a and b, as used in the present invention, represent length having a unit of μm.

FIG. 1A and FIG. 1B are drawings showing a conventional SLS crystallization method, and a rough shape of polycrystalline silicon manufactured by the method.

A mask used in a method for crystallizing amorphous silicon by the sequential lateral solidification (SLS) method has a shape in which a laser beam transmission region (width: a) and a laser beam non-transmission region (width: b) are continuously arranged.

The widths of the light transmission region and the light non-transmission region are defined as a and b, measured as the length of a straight line in a direction perpendicular to primary grain boundary.

Furthermore, “primary” grain boundaries existing in active channel regions are defined as grain boundaries having a fatal effect on TFT characteristics. Primary grain boundaries have a fatal effect when the inclination angle of grain boundaries to a direction perpendicular to an active channel direction is −45°≦Θ≦45°. The distance between “secondary” grain boundaries, formed perpendicularly to the primary grain boundaries, is defined as the width (W) of the grain boundaries, and is generally defined as the distance between secondary grain boundaries that is within the error range.

When a laser beam is irradiated onto an amorphous silicon thin film layer through the mask, a polycrystalline silicon thin film layer, having long cylindrical grains in a direction, is formed on a region through which the laser beam transmits. Polycrystalline silicon grains cannot be laterally grown by the melting and solidification of amorphous silicon while the amorphous silicon remains under a region of the mask through which the laser beam can not transmit.

As illustrated in FIG. 1 B, amorphous silicon and crystalline silicon are melted by moving a mask through stages of movement, thereby overlappingly irradiating the laser beam onto the mask to expose an amorphous silicon thin film layer and a part of an already crystallized polycrystalline silicon layer. Afterward, grains are grown to form cylindrical grains which have width W, and are long in a direction, with silicon atoms being adhered to the already formed polycrystalline silicon grains that are not melted, due to being covered with the mask, as the melted amorphous silicon and crystalline silicon are being cooled.

On the other hand, previously formed grains of the overlapped part are melted again, and the width (W) of the crystallized polycrystalline silicon grains is varied by the width (O) of a melted region of the previously formed grains of the overlapped part in the case of overlappingly irradiating the laser beam.

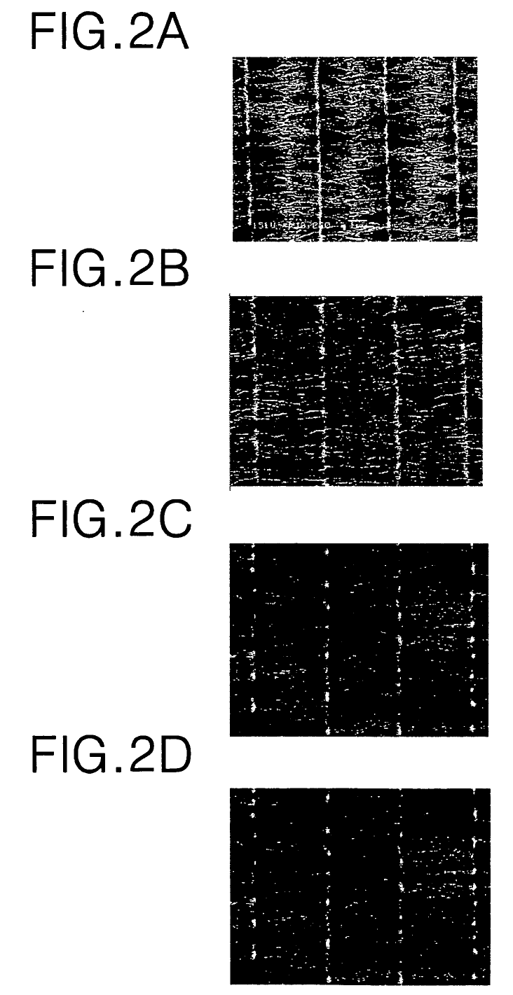

FIG. 2A to FIG. 2D are photographs showing the structures of polycrystalline silicon grains formed by varying the width of the overlapped region to 0.5, 1, 1.5 and 2 μm, respectively, according to embodiments of the present invention.

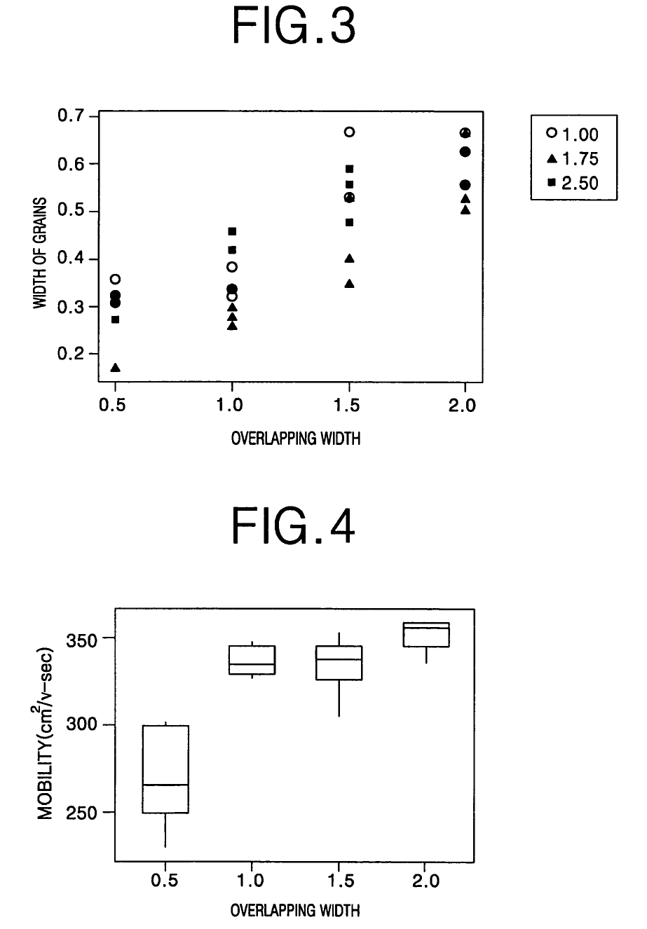

FIG. 3 is a graph showing a value for quantifying the width of grains at positions which are respectively 1, 1.75 and 2.5 μm distanced from primary grain boundaries in a polycrystalline silicon thin film having a length of 3.5 μm and the grain structure of FIG. 2A to FIG. 2D.

Referring to FIG. 2A to FIG. 2D and FIG. 3, the width of the grains is 0.6 μm or more in the case that the width of the overlapping region is 2 μm, and the width of the grains is about 0.2 μm in the case that the width of the overlapping region is reduced to 0.5 μm. A width (W) of polycrystalline silicon grains is decreased if the width (O) of a region onto which a laser beam is overlappingly irradiated is decreased.

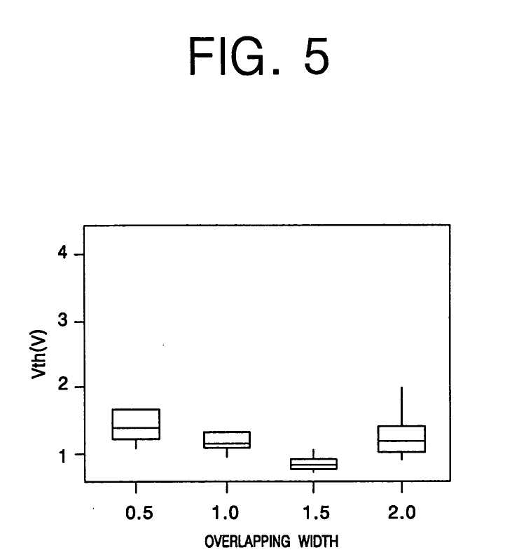

FIG. 4 is a graph showing an electric field mobility of a TFT fabricated using a polycrystalline silicon thin film having the structure of FIG. 2A to FIG. 2D, and FIG. 5 is a graph showing threshold voltage characteristics of a TFT fabricated using the polycrystalline silicon thin film having the structure of FIG. 2A to FIG. 2D.

Referring to FIG. 4 and FIG. 5, large overlapping shows superior TFT characteristics having a high electric field mobility and a low threshold voltage. 1 μm or more of overlapping, in which an average width of grains is larger than 0.2 μm, shows a relatively small difference of TFT characteristics according to the extent of overlapping, and produces superior TFT characteristics. Contrarily, 0.5 μm of overlapping, in which an average width of polycrystalline silicon grains is about 0.2 μm, shows a substantially lowered electric field mobility, increased threshold voltage, and nonuniform characteristics between TFTs.

Therefore, a polycrystalline silicon thin film in which an average width of grains is 0.2 μm or more can be formed if the width of a region on which a laser beam is overlappingly irradiated during crystallization is more than 0.5 μm, and a TFT fabricated using the polycrystalline silicon thin film has uniform and superior characteristics.

Namely, an overlapped part in a relation between a of FIG. 1A, which is a transparent region, and b of FIG. 1A, which is an opaque region, is a-b, and a polycrystalline silicon thin film in which an average width of grains is 0.2 μm or more can be formed if the overlapped part a-b is 1 μm or more.

This can be arranged as the following expression:

a>b+1, (Expression)

where unit of measure of the expression is μm, a is the width of a laser transmission region, and b is the width of a laser non-transmission region.

The SLS method may be used as the laser crystallization method used in the present invention.

Furthermore, a mask having a rectangular shape may be used as the mask used in the present invention.

As described above, the present invention increases the width of grains to a certain size or more, and is capable of manufacturing a polycrystalline silicon thin film for TFTs having superior characteristics accordingly, by optimizing a region in which a laser beam is irradiated onto an already formed crystalline silicon during SLS crystallization.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A method of manufacturing polycrystalline silicon thin film using a laser beam to crystallize amorphous silicon thin film, the method comprising overlappingly irradiating the laser beam onto a region wider than 0.5 μm when crystallizaing the amorphous silicon thin film.

2. The method of manufacturing polycrystalline silicon thin film according to claim 1, wherein the region onto which the laser beam is overlappingly irradiated is larger than 1 μm.

3. The method of manufacturing polycrystalline silicon thin film according to claim 1, wherein SLS (sequential lateral solidification) is used.

4. A thin film transistor comprising the polycrystalline silicon thin film manufactured according to the method of claim 1.

5. The thin film transistor according to claim 4, wherein an average width of grains of the polycrystalline silicon thin film is at least 0.2 μm.

6. A method of manufacturing polycrystalline silicon thin film by crystallizing amorphous silicon using a laser beam, the method comprising using a mask with a laser transmission region that is wider than a laser non-transmission region by more than 1 μm.

7. The method of manufacturing polycrystalline silicon thin film according to claim 6, wherein the mask is formed in a rectangular shape.

8. The method of manufacturing polycrystalline silicon thin film according to claim 6, wherein an overlappingly irradiated width of the thin film is larger than 0.5 μm.

9. The method of manufacturing polycrystalline silicon thin film according to claim 8, wherein the overlappingly irradiated width is 1 μm or more.

10. The method of manufacturing polycrystalline silicon thin film according to claim 6, wherein SLS (sequential lateral solidification) is used.

11. A thin film transistor comprising the polycrystalline silicon thin film manufactured according to the method of claim 6.

12. The thin film transistor according to claim 11, wherein an average width of grains of the polycrystalline silicon is at least 0.2.

13. A method of manufacturing polycrystalline silicon thin film, the method comprising overlappingly irradiating already formed crystalline silcon in a region with a width larger than 0.5 μm.

14. The method according to claim 13, wherein the overlapping irradiation is done by moving a laser transmission region of a mask more than 0.5 μm.

15. A thin film transistor comprising a polycrystalline thin film having an average grain width of at least 0.2 μm, wherein the thin film was formed by overlappingly irradiating a region of the thin film, the region being more than 0.5 μm wide.
